(19) United States
(12) Patent Application Publication
(10) Pub. No.: US 2011/0210443 A1
(43) Pub. Date: Sep. 1, 2011

(54) SEMICONDUCTOR DEVICE HAVING BUCKET-SHAPED UNDER-BUMP METALLIZATION AND METHOD OF FORMING SAME

(75) Inventors: Michael J. Hart, Palo Alto, CA (US); Jan L. de Jong, Cupertino, CA (US); Paul Y. Wu, Saratoga, CA (US)

(73) Assignee: XILINX, INC., San Jose, CA (US)

(21) Appl. No.: 12/713,855

(22) Filed: Feb. 26, 2010

(51) Int. Cl. H01L 23/498; H01L 21/768

(52) U.S. Cl. 257/738; 438/612; 257/E21.589; 257/E23.068

(57) ABSTRACT

An embodiment of a method of forming a semiconductor device that includes a substrate having an active layer and interconnect formed on the active layer is described. The method includes: forming a dielectric layer above the interconnect having a tapered via exposing at least a portion of a first metal layer; forming an under-bump metallization (UBM) layer over the tapered via and the first metal layer to form a UBM bucket; and forming a dielectric cap layer over the dielectric layer and a portion of the UBM layer. The UBM bucket is configured to support a solder ball and can advantageously block all alpha particles emitted by the solder ball having a relevant angle of incidence from reaching the active semiconductor regions of the IC. Thus, soft errors, such as single event upsets in memory cells, are reduced or eliminated.

### FIELD OF THE INVENTION

An embodiment of the present invention relates generally to semiconductor devices and, more particularly, to a semiconductor device having bucket-shaped under-bump metallization (UBM) and a method of forming the same.

### BACKGROUND

Integrated circuits (ICs) fabricated using complementary metal oxide semiconductor (CMOS) technologies are susceptible to alpha particles. Alpha particles may cause single event upsets or soft errors during operation of the IC. In particular, alpha particles can cause ionizing radiation when passing through semiconductor device junctions. The ionizing radiation can upset or flip the state of various semiconductor structures, such as a memory cell (e.g., static random access memory (SRAM) cell, such as a conventional 6-transistor or 6T-SRAM). A common source of alpha particles is the bump material used in assembling, packaging, and/or mounting ICs. For example, the Controlled-Collapse Chip Connection (C4) packaging technology utilizes solder bumps deposited on solder wettable metal terminals of the IC and a matching footprint of solder wettable terminals on a substrate. The solder typically includes approximately 95% to 97% by weight of lead (Pb), with the remainder being made up by tin (Sn), although other materials and percentages of materials can be employed. In general, the most common material used for bumps is lead or a lead alloy. As is well known in the art, lead is a source of alpha particles. Alpha particles from solder bumps can penetrate through the interconnect layer of an IC and reach the underlying semiconductor structures, potentially causing the aforementioned single event upsets.

Accordingly, there exists a need in the art for a method and apparatus for a semiconductor device and method of fabrication thereof configured to block alpha particles emitted by solder balls used in device packaging.

### SUMMARY

An embodiment of the invention relates to a method of forming a semiconductor device including a substrate having an active layer and interconnect formed on the active layer. In this embodiment, the method includes: forming a dielectric layer above the interconnect having a tapered via exposing at least a portion of a first metal layer; forming an under-bump metallization (UBM) layer over the tapered via and the first metal layer to form a UBM bucket; and forming a dielectric cap layer over the dielectric layer and a portion of the UBM layer

Another embodiment of the invention relates to a method of forming a semiconductor device including a substrate having an active layer and interconnect formed on the active layer. In this embodiment, the method comprises: forming a dielectric layer above the interconnect having a via exposing at least a portion of a bond pad of the interconnect; forming a metal seed layer over the bond pad an on sidewalls of the via; and forming a under-bump metallization (UBM) layer over the metal seed layer to form a UBM bucket.

Yet another embodiment of the invention relates to a semiconductor device. In this embodiment, the semiconductor device includes: a substrate having an active layer and interconnect formed on the active layer; a dielectric layer above the interconnect layer having a tapered via exposing at least a portion of a first metal layer; an under-bump metallization (UBM) layer forming a UBM bucket over the tapered via and the first metal layer; and a dielectric cap layer formed on the dielectric layer and a portion of the UBM layer.

### BRIEF DESCRIPTION OF THE DRAWINGS

Accompanying drawing(s) show exemplary embodiment(s) in accordance with one or more aspects of the invention; however, the accompanying drawing(s) should not be taken to limit the invention to the embodiment(s) shown, but are for explanation and understanding only.

FIG. 1 is a cross-section of a semiconductor device according to the prior art;

FIG. 2 is a cross-section of a semiconductor device according to one or more embodiments of the invention;

FIG. 3 is a flow diagram depicting a method of forming a semiconductor device according to one or more embodiments of the invention;

FIGS. 4A-4D depict semiconductor device cross-sections corresponding to steps of the method of FIG. 3;

FIG. 5 is a flow diagram depicting another method of forming a semiconductor device according to one or more embodiments of the invention;

FIGS. 6A-6E depict semiconductor device cross-sections corresponding to steps of the method of FIG. 5;

FIG. 7 is a flow diagram depicting another method of forming a semiconductor device according to one or more embodiments of the invention;

FIGS. 8A-8D depict semiconductor device cross-sections corresponding to steps of the method of FIG. 7; and

FIG. 9 is a flow diagram depicting another method of forming a semiconductor device according to one or more embodiments of the invention.

### DETAILED DESCRIPTION

A semiconductor device having bucket-shaped under-bump metallization (UBM) and a method of forming the same is described. In some embodiments, a dielectric layer is patterned over the passivation layer of an IC substrate to have vias exposing bond pads. In some embodiments, the vias are tapered vias. A UBM layer is formed in the via such that a UBM bucket is formed over the bond pad. The IC substrate can then be bumped such that solder balls are formed in the UBM buckets. Alpha particles from the portion of the solder ball in the UBM bucket are blocked by the UBM metal from penetrating and affecting the active layer of the substrates. Alpha particles from the portion of the solder ball above the UBM bucket have angles of incidence and/or path lengths that prevent such particles from reaching the active circuitry. Thus, the UBM bucket reduces or eliminates penetration of alpha particles to the active circuitry, thereby reducing or eliminating single event upsets caused by such alpha particles. These and further aspects of the invention may be understood with reference to the following drawings.

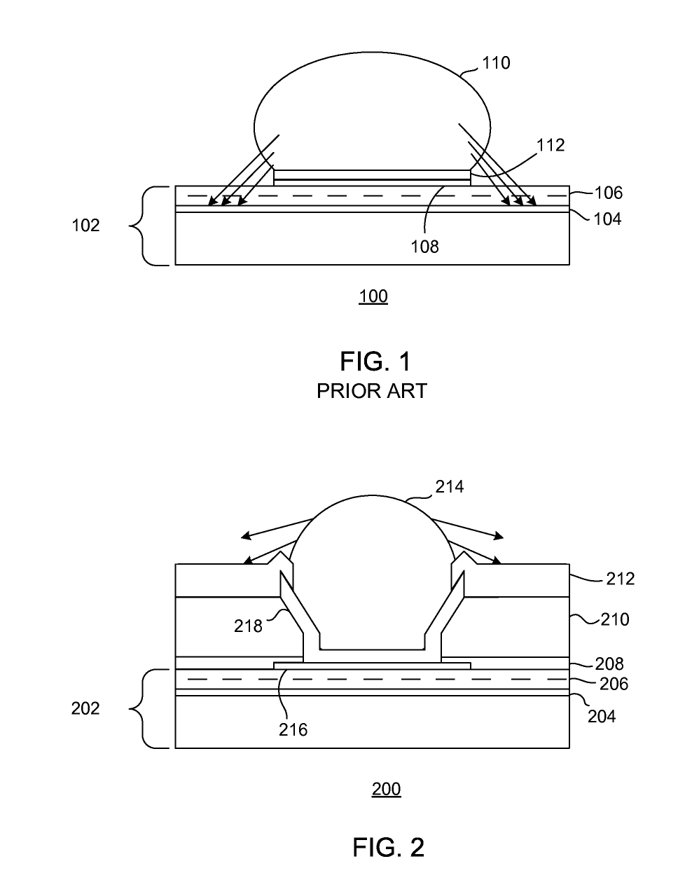

FIG. 1 is a cross-section of a semiconductor device 100 according to the prior art. The semiconductor device 100 includes a substrate 102 having an active surface 104 and interconnect 106 disposed on the active surface 104. The interconnect 106 includes a bond pad 108. In a typical flip-chip packaging process, such as C4 packaging, an under-bump metal (UBM) layer 112 is formed over the bond pad 108. A solder bump 110 is then formed on the UBM layer 112. The UBM layer 112 is a flat metal layer that is self-aligned to the solder bump 110 such that the solder bump protrudes beyond the UBM layer 112 at its periphery. While the UBM layer 112 may be thick enough to block alpha particles emitted from the central lower surface of the solder bump 110, the UBM layer 112 does not block alpha particles emitted from areas of the solder bump 110 that protrude beyond the UBM layer 112. Alpha particles other than those close to vertical incidence will bypass the UBM layer 112 and could reach the underlying active surface 104. Thus, a “donut” shape of single event upsets can be detected in underlying circuits on the active surface 104 caused by peripheral and non-vertical incidence alpha particles emitted by the solder ball 110.

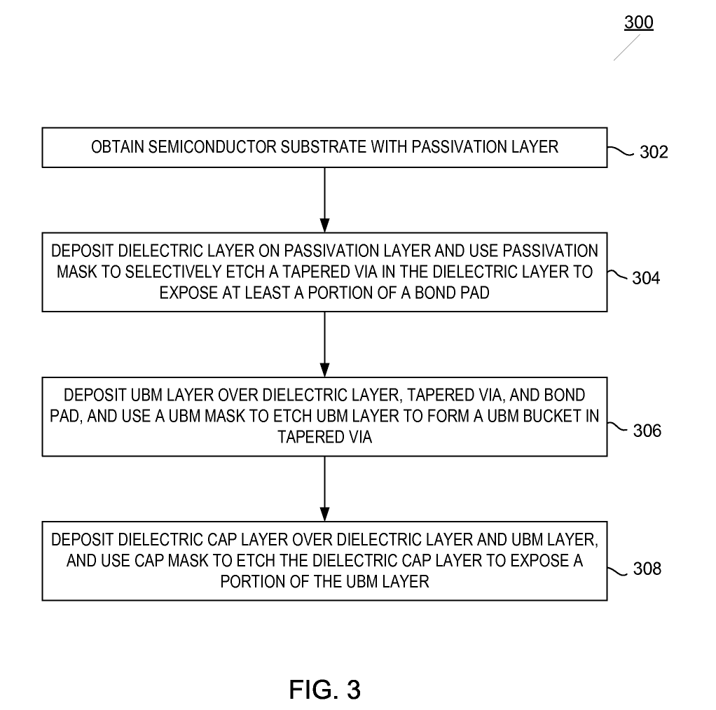

FIG. 2 is a cross-section of a semiconductor device 200 according to one or more embodiments of the invention. The semiconductor device 200 includes a substrate 202 having an active surface 204 and interconnect 206 disposed on the active surface 204. The interconnect 206 can include multiple layers of conductive interconnect, including a top-most layer having bond pads, such as bond pad 216. A passivation layer 208 is formed over the substrate 202, exposing at least a portion of the bond pad 216. A dielectric layer 210 is formed over the passivation layer 208. A tapered via is formed through the dielectric layer 210 exposing the bond pad 216. A “tapered via” is a hole through the layer that is at least partially frusto-conical in shape (a portion of the tapered via may be cylindrical in shape). A UBM layer 218 is formed in the tapered via and over the bond pad 216. Thus, a “bucket-shaped” UBM is formed for supporting a solder ball 214. A dielectric cap layer 212 is formed on the dielectric layer 210 and over a portion of the UBM layer 218 (e.g., the portion of the UBM layer 218 that protrudes above the dielectric layer 210).

The dielectric and passivation layers may be formed of any dielectric material known in the art, such as SiO₂. The UBM layer 218 may be formed of various metals or metal alloys comprising Ti, Ni, Cu, Zn, Sn, and the like. The UBM layer 218 may have a thickness adapted to sufficiently block alpha particles. For example, in some non-limiting embodiments, the UBM layer 218 made of a Cu/Ni alloy may have a thickness between 5 and 10 μm. The solder ball 214 fully fills the bucket of the UBM layer 218 and includes a portion extending above the dielectric layer 212. Alpha particles emitted anywhere from the portion of the solder ball 214 in the UBM bucket are blocked by the UBM layer 218. Alpha particles emitted anywhere from the portion of the solder ball 214 extending above the dielectric cap layer 212 are not blocked, but have an angle of incidence and/or path lengths such that the particles will not penetrate through to the active surface 204. In this manner, the bucket-shaped UBM in the UBM layer 218 reduces or eliminates single event upsets during IC operation caused by alpha particles.

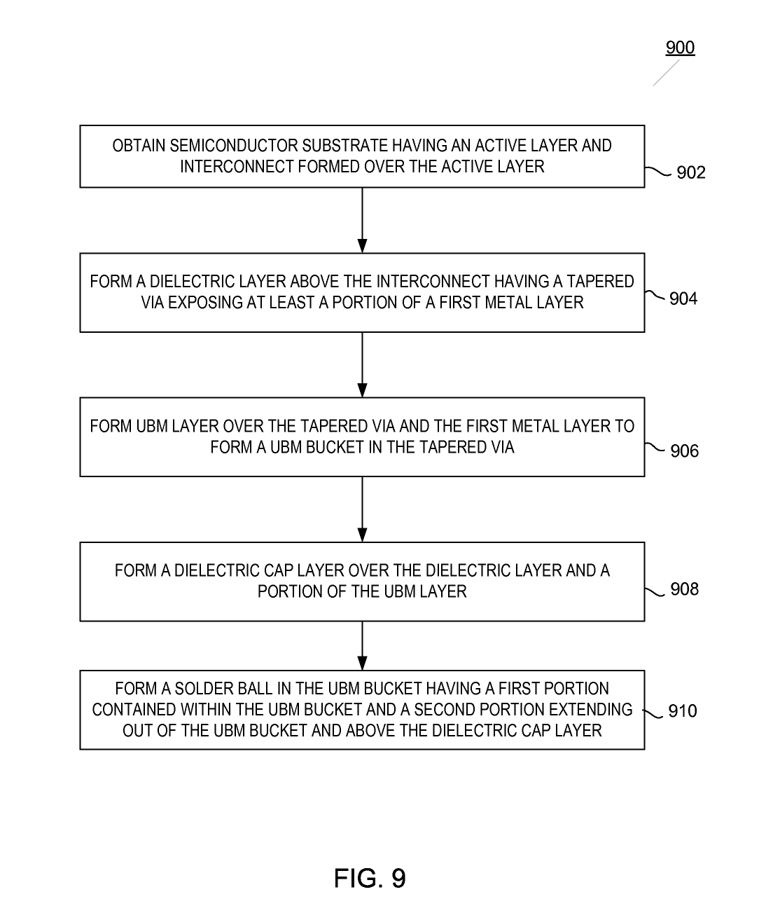

FIG. 9 is a flow diagram depicting a method 900 of forming a semiconductor device according to one or more embodiments of the invention. The method 900 begins at step 902, where a semiconductor substrate having an active layer and interconnect formed on the active layer is obtained. At step 904, a dielectric layer is formed above the interconnect having a tapered via exposing at least a portion of a first metal layer. In some embodiments, the first metal layer is a bond pad on a top-most layer of the interconnect. In other embodiments, the first metal layer is a first UBM layer formed on a bond pad of the interconnect. In some embodiments, the dielectric layer is a passivation layer formed on the interconnect. In other embodiments, the dielectric layer is formed over a passivation layer formed on the interconnect. At step 906, a UBM layer is formed over the tapered via and the first metal layer to form a UBM bucket in the tapered via. The UBM layer in step 906 may be a second UBM layer in embodiments where the first metal layer is a first UBM layer. At step 908, a dielectric cap layer is formed over the dielectric layer and a portion of the UBM layer forming the UBM bucket. At step 910, a solder ball can be formed in the UBM bucket having a first portion contained within the UBM bucket and a second portion extending above the dielectric cap layer. More detailed exemplary embodiments of the method 900 are described below.

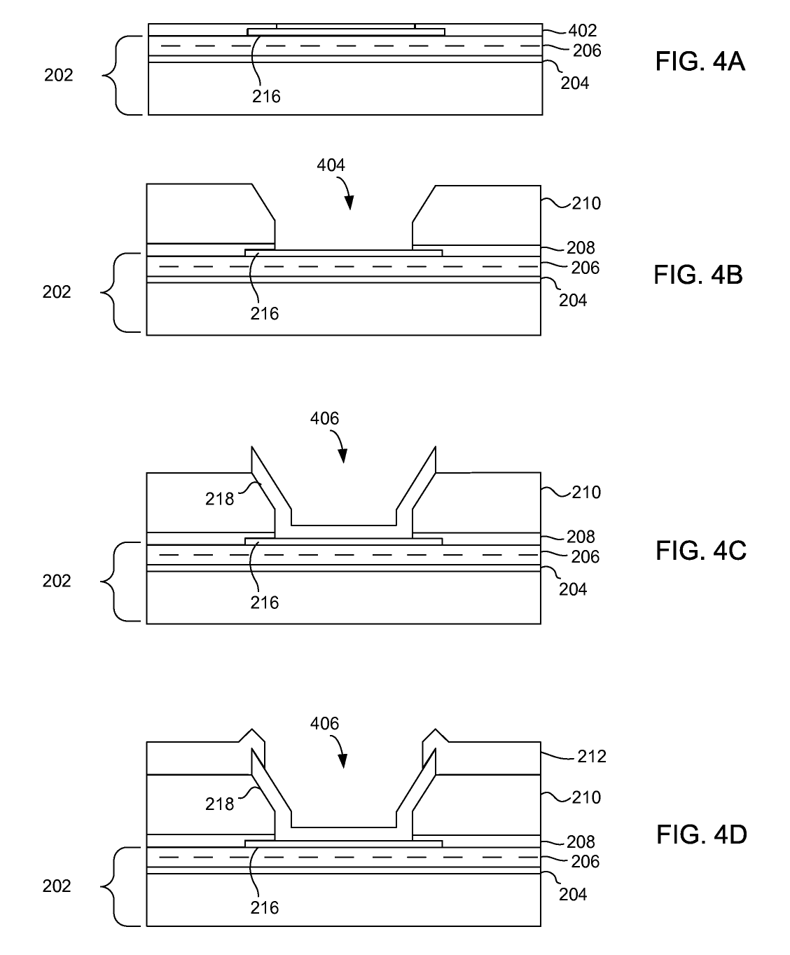

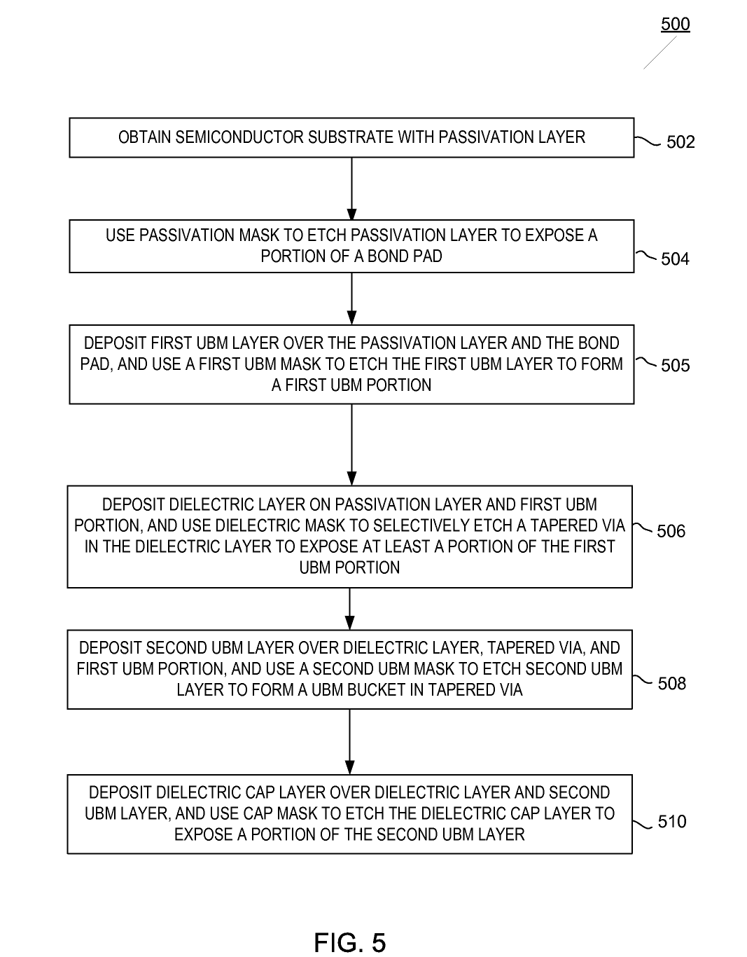

FIG. 3 is a flow diagram depicting a method 300 of forming a semiconductor device according to one or more embodiments of the invention. FIGS. 4A-4D depict semiconductor device cross-sections corresponding to steps of the method 300. Elements in FIGS. 4A-4D that are the same or similar to those of FIG. 2 are designated with identical reference numerals. At step 302, a semiconductor substrate having a passivation layer formed thereon is obtained. FIG. 4A shows the substrate 202 having a passivation layer 402 formed on the interconnect 206. The substrate 202 may be formed using conventional semiconductor processes.

At step 304, a dielectric layer is deposited on the passivation layer and a passivation mask is used to selectively etch a tapered via in the dielectric layer to expose at least a portion of a bond pad. The tapered via may be formed using conventional deposition, photolithographic, and etching processes. FIG. 4B shows the passivation and dielectric layers 208 and 210 and a tapered via 404 formed therein. The dielectric layer 210 may be thick relative to the passivation layer 208. For example, in a non-limiting embodiment, the dielectric layer 210 may have a thickness between 20 and 60 μm (whereas the passivation layer 208 may have a thickness between 5 and 7 μm). The dielectric layer 210 may be generally sized according to the size of the solder balls used in device packaging.

At step 306, a UBM layer is deposited over the dielectric layer, tapered via and bond pad, and a UBM mask is used to selectively etch the UBM layer to form a UBM bucket in the tapered via. The UBM bucket may be formed using conventional deposition, photolithographic, and etching processes. The UBM mask may be oversized from the baseline UBM layer such that the UBM bucket fills the tapered via. FIG. 4C shows the UBM layer 218 having a UBM bucket 406 formed over the bond pad 216.

At step 308, a dielectric cap layer is deposited over the dielectric layer and the UBM layer, and a cap mask is used to selectively etch the dielectric cap layer to expose a portion of the UBM layer. The openings for the UBM layer may be formed using conventional deposition, photolithographic, and etching processes. The cap mask may be oversized from the passivation mask such that the dielectric cap layer covers the portions of the UBM bucket that extend above the dielectric layer. FIG. 4D shows the dielectric cap layer 212 formed over the dielectric layer 210 and a portion of the UBM layer 218. A solder ball can then be formed in the UBM bucket 406, as shown in FIG. 2.

In some embodiments, the dielectric layer 210 can be omitted, and the passivation layer 208 can be formed having the same or similar thickness as the dielectric layer 210.

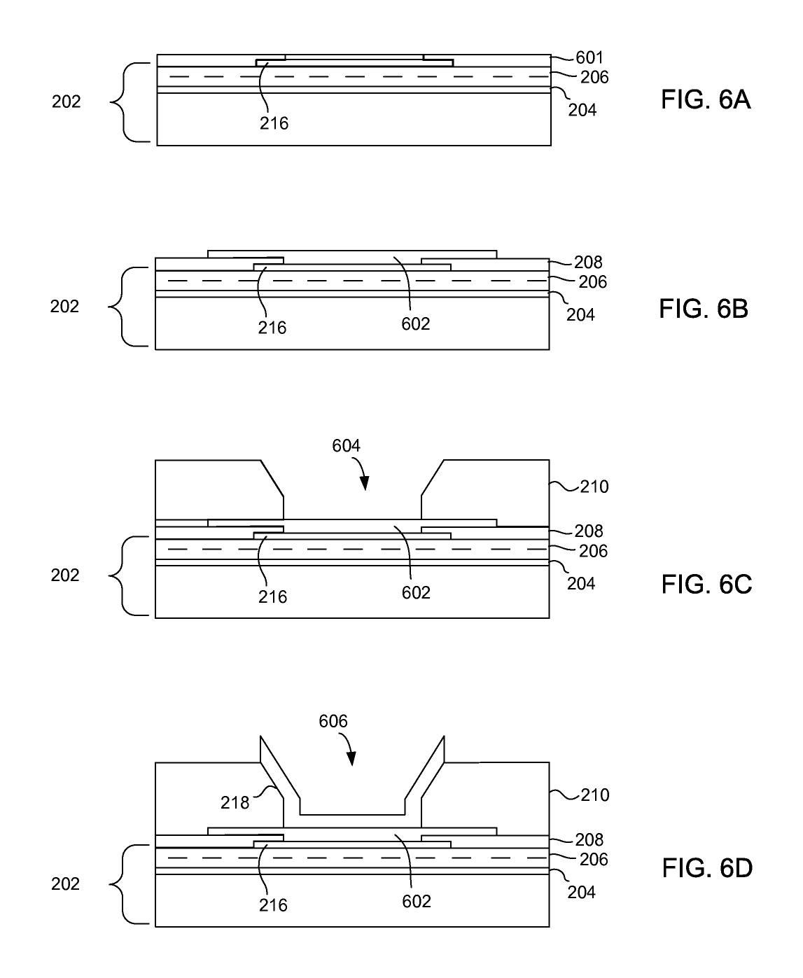

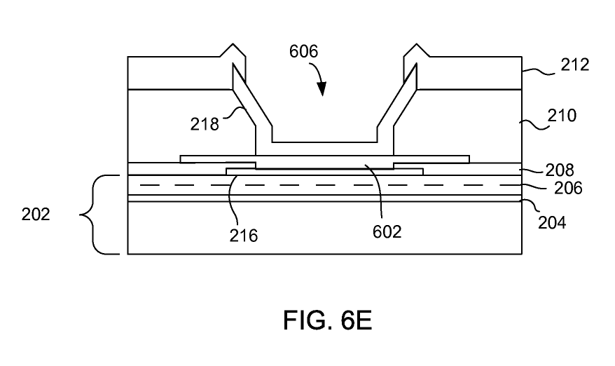

FIG. 5 is a flow diagram depicting a method 500 of forming a semiconductor device according to one or more embodiments of the invention. FIGS. 6A-6E depict semiconductor device cross-sections corresponding to steps of the method 500. Elements in FIGS. 6A-6E that are the same or similar to those of FIG. 2 are designated with identical reference numerals. At step 502, a semiconductor substrate having a passivation layer formed thereon is obtained. FIG. 6A shows the substrate 202 having a passivation layer 601 formed on the interconnect 206. The substrate 202 may be formed using conventional semiconductor processes.

At step 504, a passivation mask is used to etch the passivation layer to expose a portion of each bond pad. At step 505, a first UBM layer is deposited over the passivation layer and the bond pad, and a first UBM mask is used to etch the first UBM layer to form a first UBM portion. The first UBM portion can be formed using conventional deposition, photolithographic, and etching techniques. FIG. 6B shows a first UBM portion 602 formed over the passivation layer 208 and the bond pad 216.

At step 506, a dielectric layer is deposited on the passivation layer and the first UBM portion, and a dielectric mask is used to selectively etch a tapered via in the dielectric layer to expose at least a portion of the first UBM portion. The tapered via may be formed using conventional deposition, photolithographic, and etching processes. FIG. 6C shows the dielectric layer 210 and a tapered via 604 formed therein. The dielectric layer 210 may be thick relative to the passivation layer 208. For example, in a non-limiting embodiment, the dielectric layer 210 may have a thickness between 20 and 60 μm. The dielectric layer 210 may be generally sized according to the size of the solder balls used in device packaging.

At step 508, a second UBM layer is deposited over the dielectric layer, tapered via and first UBM portion, and a second UBM mask is used to selectively etch the second UBM layer to form a UBM bucket in the tapered via. The UBM bucket may be formed using conventional deposition, photolithographic, and etching processes. The second UBM mask may be oversized from the baseline UBM layer such that the UBM bucket fills the tapered via. FIG. 6D shows the UBM layer 218 having a UBM bucket 606 formed over the first UBM portion 602 in the tapered via 604.

At step 510, a dielectric cap layer is deposited over the dielectric layer and the second UBM layer, and a cap mask is used to selectively etch the dielectric cap layer to expose a portion of the second UBM layer. The openings for the second UBM layer may be formed using conventional deposition, photolithographic, and etching processes. The cap mask may be oversized from the passivation mask such that the dielectric cap layer covers the portions of the UBM bucket that extend above the dielectric layer. FIG. 6E shows the dielectric cap layer 212 formed over the dielectric layer 210 and a portion of the UBM layer 218. A solder ball can then be formed in the UBM bucket 606, as shown in FIG. 2.

The process 500 may be used to form a UBM bucket over a bond pad metal that requires two different UBM materials, such as a copper bond pad (i.e., one UBM material for adhering to the bond pad, and another UBM material for adhering to a solder ball).

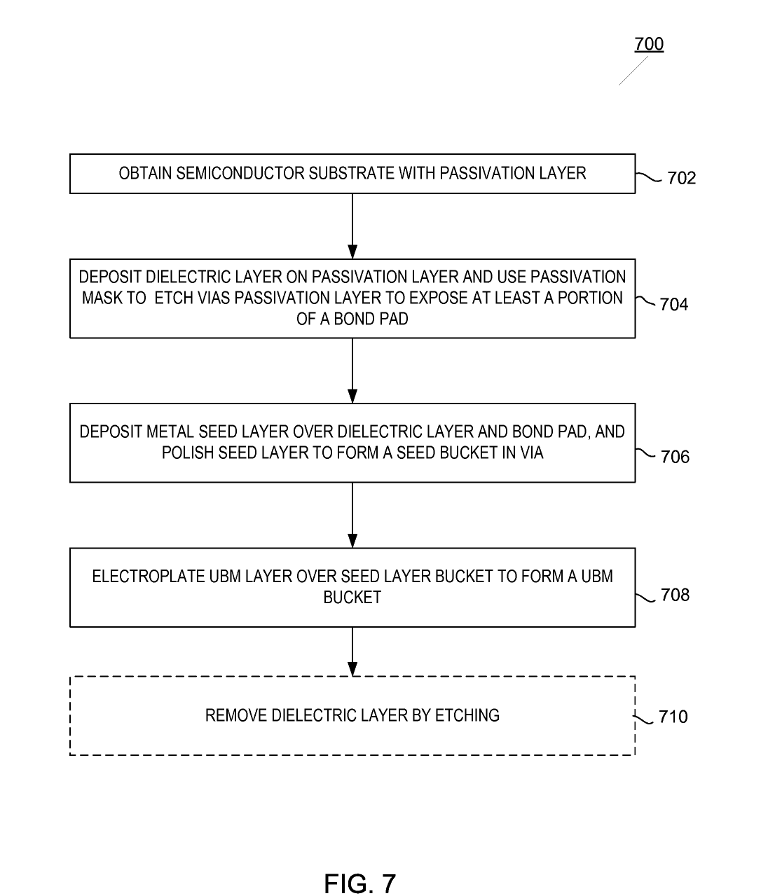

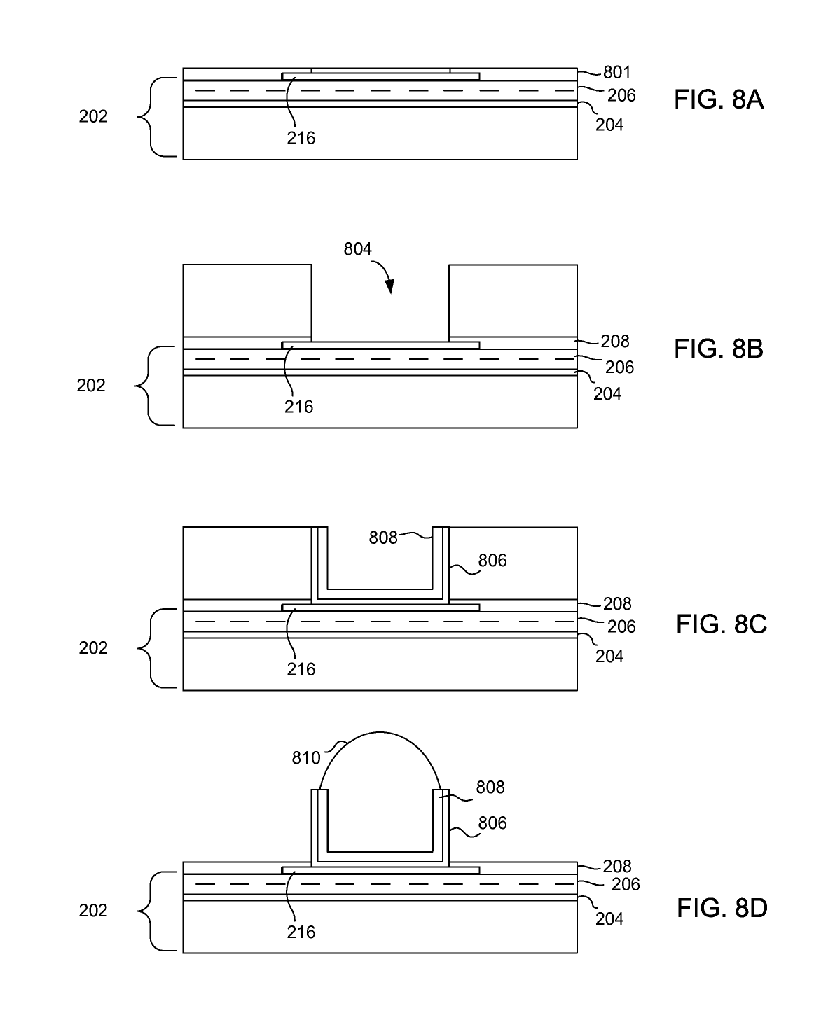

FIG. 7 is a flow diagram depicting a method 700 of forming a semiconductor device according to one or more embodiments of the invention. FIGS. 8A-8D depict semiconductor device cross-sections corresponding to steps of the method 700. Elements in FIGS. 8A-8D that are the same or similar to those of FIG. 2 are designated with identical reference numerals. At step 702, a semiconductor substrate having a passivation layer formed thereon is obtained. FIG. 8A shows the substrate 202 having a passivation layer 801 formed on the interconnect 206. The substrate 202 may be formed using conventional semiconductor processes.

At step 704, a dielectric layer is deposited over the passivation layer, and a passivation mask is used to etch the dielectric and passivation layer to expose a portion of each bond pad. FIG. 8B shows a dielectric layer 802 formed over the passivation layer 208 and having a via 804 exposing the bond pad 216. The via 804 may be cylindrical in shape. The dielectric layer 802 is thick relative to the passivation layer 208 (e.g., between 20 and 60 μm or other thickness depending on solder ball size).

At step 706, a metal seed layer is deposited over the dielectric layer and the bond pad, and the seed layer is polished to form a seed bucket in the via. At step 708, a UBM layer is electroplated over the seed bucket to form a UBM bucket. The seed and UBM buckets may be formed using conventional deposition, polishing, and electroplating processes. FIG. 8C shows a seed layer 806 and a UBM layer 808 forming a bucket over the bond pad 216 in the via of the dielectric layer 802.

At optional step 710, the dielectric layer can be removed by etching. The dielectric layer can be removed if necessary to control passivation layer stress. FIG. 8D shows the substrate 202 with the UBM bucket and the dielectric layer 802 removed. A solder ball 810 is shown formed in the UBM bucket formed by the seed layer 806 and the UBM layer 808. A first portion of the solder ball 810 is formed in the UBM bucket, and a second portion of the solder ball 810 extends above the UBM bucket. Alpha particles emitted from the first portion of the solder ball 810 in the UBM bucket are blocked by the UBM metal, and alpha particles emitted from the second portion of the solder ball 810 are not blocked, but do not penetrate to the active surface 204 due to the angle of incidence and path length.

While the foregoing describes exemplary embodiment(s) in accordance with one or more aspects of the present invention, other and further embodiment(s) in accordance with the one or more aspects of the present invention may be devised without departing from the scope thereof, which is determined by the claim(s) that follow and equivalents thereof. Claim(s) listing steps do not imply any order of the steps. Trademarks are the property of their respective owners.

What is claimed is:

1. A method of forming a semiconductor device including a substrate having an active layer and interconnect formed on the active layer, the method comprising:
forming a dielectric layer above the interconnect having a tapered via exposing at least a portion of a first metal layer;
forming an under-bump metallization (UBM) layer over the tapered via and the first metal layer to form a UBM bucket; and
forming a dielectric cap layer over the dielectric layer and a portion of the UBM layer.

2. The method of claim 1, further comprising:
forming a solder ball in the UBM bucket, the solder ball having a first portion contained within the UBM bucket and a second portion extending out of the UBM bucket and above the dielectric cap layer.

3. The method of claim 1, wherein the dielectric layer comprises a passivation layer formed on the interconnect.

4. The method of claim 1, wherein the substrate further includes a passivation layer formed on the interconnect, and wherein the dielectric layer is formed on the passivation layer.

5. The method of claim 4, wherein the UBM layer is a second UBM layer, and the method further comprises:
forming an opening in the passivation layer exposing at least a portion of a bond pad of the interconnect; and
forming a first UBM layer over the bond pad and a portion of the passivation layer, the first UBM layer being the first metal layer.

6. The method of claim 1, wherein the first metal layer comprises at least a portion of a bond pad of the interconnect.

7. The method of claim 1, wherein the tapered via is at least partially frusto-conical in shape.

8. A method of forming a semiconductor device including a substrate having an active layer and interconnect formed on the active layer, the method comprising:
forming a dielectric layer above the interconnect having a via exposing at least a portion of a bond pad of the interconnect;
forming a metal seed layer over the bond pad an on sidewalls of the via; and
forming a under-bump metallization (UBM) layer over the metal seed layer to form a UBM bucket.

9. The method of claim 8, further comprising:
forming a solder ball in the UBM bucket, the solder ball having a first portion contained within the UBM bucket and a second portion extending out of the UBM bucket and above the dielectric cap layer.

10. The method of claim 8, wherein the dielectric layer comprises a passivation layer formed on the interconnect.

11. The method of claim 8, wherein the substrate further includes a passivation layer formed on the interconnect, and wherein the dielectric layer is formed on the passivation layer.

12. The method of claim 8, further comprising:
removing the dielectric layer subsequent to forming the UBM layer and the UBM bucket.

13. A semiconductor device, comprising:
a substrate having an active layer and interconnect formed on the active layer;
a dielectric layer above the interconnect layer having a tapered via exposing at least a portion of a first metal layer;
an under-bump metallization (UBM) layer forming a UBM bucket over the tapered via and the first metal layer; and
a dielectric cap layer formed on the dielectric layer and a portion of the UBM layer.

14. The semiconductor device of claim 13, further comprising:
a solder ball disposed in the UBM bucket, the solder ball having a first portion contained within the UBM bucket and a second portion extending out of the UBM bucket and above the dielectric cap layer.

15. The semiconductor device of claim 13, wherein the dielectric layer comprises a passivation layer formed on the interconnect.

16. The semiconductor device of claim 13, wherein the substrate further includes a passivation layer formed on the interconnect, and wherein the dielectric layer is formed on the passivation layer.

17. The semiconductor device of claim 16, wherein the UBM layer is a second UBM layer, and the semiconductor device further comprises:
an opening in the passivation layer exposing at least a portion of a bond pad of the interconnect; and
a first UBM layer formed over the bond pad and a portion of the passivation layer, the first UBM layer being the first metal layer.

18. The semiconductor device of claim 13, wherein the first metal layer comprises at least a portion of a bond pad of the interconnect.

19. The semiconductor device of claim 13, wherein the tapered via is at least partially frusto-conical in shape.
